(19) United States
(12) Patent Application Publication
(10) Pub. No.: US 2008/0099181 A1
(43) Pub. Date: May 1, 2008

(54) METHOD TO COOL A BAKE PLATE USING AN ACTIVELY CHILLED TRANSFER SHUTTLE

(75) Inventors: Natarajan Ramanan, San Jose, CA (US); Jay D. Pinson, San Jose, CA (US); Anzhong Chang, San Jose, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: SOKUDO CO., LTD., Kyoto (JP)

(21) Appl. No.: 11/691,461

(22) Filed: Mar. 26, 2007

Related U.S. Application Data
(60) Provisional application No. 60/863,772, filed on Oct. 31, 2006.

(51) Int. Cl. H01L 21/00

(52) U.S. Cl. 165/61

(57) ABSTRACT

A method of performing a temperature set point change for a bake plate of a track lithography tool includes positioning a cooling surface of an actively chilled transfer shuttle adjacent a process surface of the bake plate. The actively chilled transfer shuttle includes the cooling surface and a transfer surface opposing the cooling surface. The method also includes monitoring a temperature of the bake plate, initiating a flow of a cooling fluid through one or more orifices provided on the cooling surface of the actively chilled transfer shuttle, and determining that the temperature of the bake plate has decreased by a predetermined temperature. The method further includes terminating the flow of the cooling fluid and moving the actively chilled transfer shuttle to a robot transfer position.

### CROSS-REFERENCES TO RELATED APPLICATIONS

The present application claims benefit under 35 U.S.C. § 119(e) of U.S. Provisional Patent Application No. 60/863,772, filed Oct. 31, 2006, entitled “Method to Cool a Bake Plate Using an Actively Chilled Transfer Shuttle,” which is incorporated herein by reference in its entirety.

### BACKGROUND OF THE INVENTION

The present invention relates generally to the field of substrate processing equipment. More particularly, the present invention relates to a method and apparatus for cooling a bake plate of a semiconductor processing apparatus. Merely by way of example, the method and apparatus of the present invention utilize an actively chilled transfer shuttle to cool a bake plate in a bake chamber of a track lithography tool. The method and apparatus can be applied to other characterization devices for semiconductor processing equipment utilized in other processing chambers.

Modern integrated circuits contain millions of individual elements that are formed by patterning the materials, such as silicon, metal and dielectric layers, that make up the integrated circuit to sizes that are small fractions of a micrometer. The technique used throughout the industry for forming such patterns is photolithography. A typical photolithography process sequence generally includes depositing one or more uniform photoresist (resist) layers on the surface of a substrate, drying and curing the deposited layers, patterning the substrate by exposing the photoresist layer to radiation that is suitable for modifying the exposed layer and then developing the patterned photoresist layer.

It is common in the semiconductor industry for many of the steps associated with the photolithography process to be performed in a multi-chamber processing system (e.g., a cluster tool) that has the capability to sequentially process semiconductor wafers in a controlled manner. One example of a cluster tool that is used to deposit (i.e., coat) and develop a photoresist material is commonly referred to as a track lithography tool.

Track lithography tools typically include a mainframe that houses multiple chambers (which are sometimes referred to herein as stations) dedicated to performing the various tasks associated with pre- and post-lithography processing. There are typically both wet and dry processing chambers within track lithography tools. Wet chambers include coat and/or develop bowls, while dry chambers include thermal control units that house bake and/or chill plates. Track lithography tools also frequently include one or more pod/cassette mounting devices, such as an industry standard FOUP (front opening unified pod), to receive substrates from and return substrates to the clean room, multiple substrate transfer robots to transfer substrates between the various stations of the track tool and an interface that allows the tool to be operatively coupled to a lithography exposure tool in order to transfer substrates into the exposure tool and to receive substrates after they have been processed within the exposure tool.

One conventional approach to cooling the bake plates is to turn off the heater power and wait for the bake plate to cool through convective flow. A drawback of this approach is that this cooling process is time-consuming, thereby lowering process chamber throughput. An alternative conventional approach is to place a metal heat-sink in contact with the bake plate. Although this method generally provides more rapid cooling than convective air cooling, this method results in the generation of particles, which may lead to the formation of defects during the semiconductor fabrication process. In view of these requirements, methods and systems for improved cooling of bake plates and other semiconductor process tools are needed.

### SUMMARY OF THE INVENTION

According to the present invention, techniques related to the field of substrate processing equipment are provided. More particularly, the present invention relates to a method and apparatus for cooling a bake plate of a semiconductor processing apparatus. Merely by way of example, the method and apparatus of the present invention utilize an actively chilled transfer shuttle to cool a bake plate in a bake chamber of a track lithography tool. The method and apparatus can be applied to other characterization devices for semiconductor processing equipment utilized in other processing chambers.

According to an embodiment of the present invention a method of performing a set point change process for a bake plate of a semiconductor process tool is provided. The method includes moving an actively chilled transfer shuttle to a position adjacent a process surface of the bake plate. The actively chilled transfer shuttle includes a transfer surface and a cooling surface opposing the transfer surface. The method also includes monitoring a temperature of the bake plate and reducing the temperature of the bake plate to a predetermined temperature. The method further includes moving the actively chilled transfer shuttle to a robot transfer position.

According to another embodiment of the present invention, a method of performing a temperature set point change for a bake plate of a track lithography tool is provided. The method includes positioning a cooling surface of an actively chilled transfer shuttle adjacent a process surface of the bake plate. The actively chilled transfer shuttle includes the cooling surface and a transfer surface opposing the cooling surface. The method also includes monitoring a temperature of the bake plate, initiating a flow of a cooling fluid through one or more orifices provided on the cooling surface of the actively chilled transfer shuttle, and determining that the temperature of the bake plate has decreased by a predetermined temperature. The method further includes terminating the flow of the cooling fluid and moving the actively chilled transfer shuttle to a robot transfer position.

Many benefits are achieved by way of the present invention over conventional techniques. For example, embodiments of the present invention reduce the time utilized to cool a bake plate, thereby increasing process chamber throughput. Additionally, embodiments of the present invention provide for uniform heat removal rates across the surface of the bake plate, thereby reducing the time used to bring the bake plate to a uniform temperature distribution at the new set point. Depending upon the embodiment, one or more of these benefits, as well as other benefits, may be achieved. These and other benefits will be described in more detail throughout the present specification and more particularly below in conjunction with the following drawings.

### BRIEF DESCRIPTION OF THE DRAWINGS

FIG. 1 is a simplified plan view of a track lithography tool according to an embodiment of the present invention;

FIG. 2 is a simplified cut-away perspective view of a thermal unit according to an embodiment of the present invention;

FIG. 3 is a perspective view of a cross-section of a bake station according to an embodiment of the present invention;

FIG. 4A is a first simplified perspective view of an actively chilled transfer shuttle according to an embodiment of the present invention;

FIG. 4B is a second simplified perspective view of an actively chilled transfer shuttle according to an embodiment of the present invention;

FIG. 5A is a simplified flowchart illustrating a method of performing a set point change for a bake plate according to an embodiment of the present invention;

FIG. 5B is a simplified flowchart illustrating another method of performing a set point change for a bake plate according to an alternative embodiment of the present invention;

FIG. 6 is a simplified plot of the bake plate temperature profile as a function of time according to embodiments of the present invention; and

FIG. 7 is a simplified plot of bake plate zone temperatures as a function of time according to an embodiment of the present invention.

### DETAILED DESCRIPTION OF SPECIFIC EMBODIMENTS

According to the present invention, techniques related to the field of substrate processing equipment are provided. More particularly, the present invention relates to a method and apparatus for cooling a bake plate of a semiconductor processing apparatus. Merely by way of example, the method and apparatus of the present invention utilize an actively chilled transfer shuttle to cool a bake plate in a bake chamber of a track lithography tool. The method and apparatus can be applied to other characterization devices for semiconductor processing equipment utilized in other processing chambers.

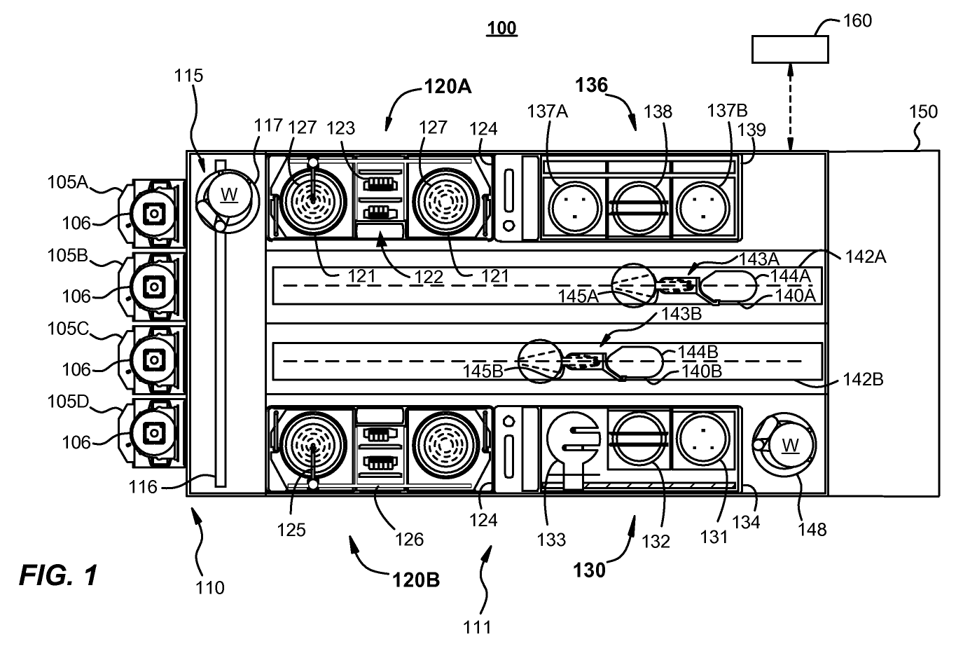

FIG. 1 is a plan view of an embodiment of a track lithography tool in which the embodiments of the present invention may be used. As illustrated in FIG. 1, the track lithography tool contains a front end module 110 (sometimes referred to as a factory interface) and a process module 111. In other embodiments, the track lithography tool includes a rear module (not shown), which is sometimes referred to as a scanner interface. Front end module 110 generally contains one or more pod assemblies or FOUPS (e.g., items 105A-D) and a front end robot assembly 115 including a horizontal motion assembly 116 and a front end robot 117. The front end module 110 may also include front end processing racks (not shown). The one or more pod assemblies 105A-D are generally adapted to accept one or more cassettes 106 that may contain one or more substrates or wafers that are to be processed in the track lithography tool. The front end module 110 may also contain one or more pass-through positions (not shown) to link the front end module 110 and the process module 111.

Process module 111 generally contains a number of processing racks 120A, 120B, 130, and 136. As illustrated in FIG. 1, processing racks 120A and 120B each include a coater/developer module with shared dispense 124. A coater/developer module with shared dispense 124 includes two coat bowls 121 positioned on opposing sides of a shared dispense bank 122, which contains a number of dispense nozzles 123 providing processing fluids (e.g., bottom anti-reflection coating (BARC) liquid, resist, developer, and the like) to a wafer mounted on a substrate support 127 located in the coat bowl 121. In the embodiment illustrated in FIG. 1, a nozzle positioning member 125 sliding along a track 126 is able to pick up a dispense nozzle 123 from the shared dispense bank 122 and position the selected dispense nozzle over the wafer for dispense operations. Coat bowls with dedicated dispense banks are provided in alternative embodiments.

Processing rack 130 includes an integrated thermal unit 134 including a bake plate 131, a chill plate 132 and a shuttle 133. The bake plate 131 and the chill plate 132 are utilized in heat treatment operations including post exposure bake (PEB), post-resist bake, and the like. In some embodiments the shuttle 133, which moves wafers in the x-direction between the bake plate 131 and the chill plate 132, is chilled to provide for initial cooling of a wafer after removal from the bake plate 131 and prior to placement on the chill plate 132. Moreover, in other embodiments shuttle 133 is adapted to move in the z-direction, enabling the use of bake and chill plates at different z-heights. Processing rack 136 includes an integrated bake and chill unit 139, with two bake plates 137A and 137B served by a single chill plate 138.

One or more robot assemblies (robots) 140 are adapted to access the front-end module 110, the various processing modules or chambers retained in the processing racks 120A, 120B, 130, and 136, and the scanner 150. By transferring substrates between these various components, a desired processing sequence can be performed on the substrates. The two robots 140 illustrated in FIG. 1 are configured in a parallel processing configuration and travel in the x-direction along horizontal motion assembly 142. Utilizing a mast structure (not shown), the robots 140 are also adapted to move orthogonal to the transfer direction. Utilizing one or more of three directional motion capabilities, robots 140 are able to place wafers in and transfer wafers between the various processing chambers retained in the processing racks that are aligned along the transfer direction.

Referring to FIG. 1, the first robot assembly 140A and the second robot assembly 140B are adapted to transfer substrates to the various processing chambers contained in the processing racks 120A, 120B, 130, and 136. In one embodiment, to perform the process of transferring substrates in the track lithography tool, robot assembly 140A and robot assembly 140B are similarly configured and include at least one horizontal motion assembly 142, a vertical motion assembly 144, and a robot hardware assembly 143 supporting a robot blade 145. Robot assemblies 140 are in communication with a controller 160 that controls the system. In the embodiment illustrated in FIG. 1, a rear robot assembly 148 is also provided.

The scanner 150 is a lithographic projection apparatus used, for example, in the manufacture of integrated circuits. The scanner 150 exposes a photosensitive material that was deposited on the substrate in the cluster tool to some form of radiation to generate a circuit pattern corresponding to an individual layer of the integrated circuit device to be formed on the substrate surface.

Each of the processing racks 120A, 120B, 130, and 136 contain multiple processing modules in a vertically stacked arrangement. That is, each of the processing racks may contain multiple stacked coater/developer modules with shared dispense 124, multiple stacked integrated thermal units 134, multiple stacked integrated bake and chill units 139, or other modules that are adapted to perform the various processing steps required of a track photolithography tool. As examples, coater/developer modules with shared dispense 124 may be used to deposit a bottom antireflective coating (BARC) and/or deposit and/or develop photoresist layers. Integrated thermal units 134 and integrated bake and chill units 139 may perform bake and chill operations associated with hardening BARC and/or photoresist layers after application or exposure.

In one embodiment, controller 160 is used to control all of the components and processes performed in the cluster tool. The controller 160 is generally adapted to communicate with the scanner 150, monitor and control aspects of the processes performed in the cluster tool, and is adapted to control all aspects of the complete substrate processing sequence. The controller 160, which is typically a microprocessor-based controller, is configured to receive inputs from a user and/or various sensors in one of the processing chambers and appropriately control the processing chamber components in accordance with the various inputs and software instructions retained in the controller's memory. The controller 160 generally contains memory and a CPU (not shown) which are utilized by the controller to retain various programs, process the programs, and execute the programs when necessary. The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include cache, power supplies, clock circuits, input/output circuitry, subsystems, and the like all well known in the art. A program (or computer instructions) readable by the controller 160 determines which tasks are performable in the processing chambers. Preferably, the program is software readable by the controller 160 and includes instructions to monitor and control the process based on defined rules and input data.

It is to be understood that embodiments of the invention are not limited to use with a track lithography tool such as that depicted in FIG. 1, but may be used in any track lithography tool including the many different tool configurations described in U.S. patent application Ser. No. 11/112,281 entitled “Cluster Tool Architecture for Processing a Substrate” filed on Apr. 22, 2005, and Ser. No. 11/315,984 entitled “Cartesian Robot Cluster Tool Architecture” filed on Dec. 22, 2005, both of which are hereby incorporated by reference for all purposes. In addition, embodiments of the invention may be used in other semiconductor processing equipment.

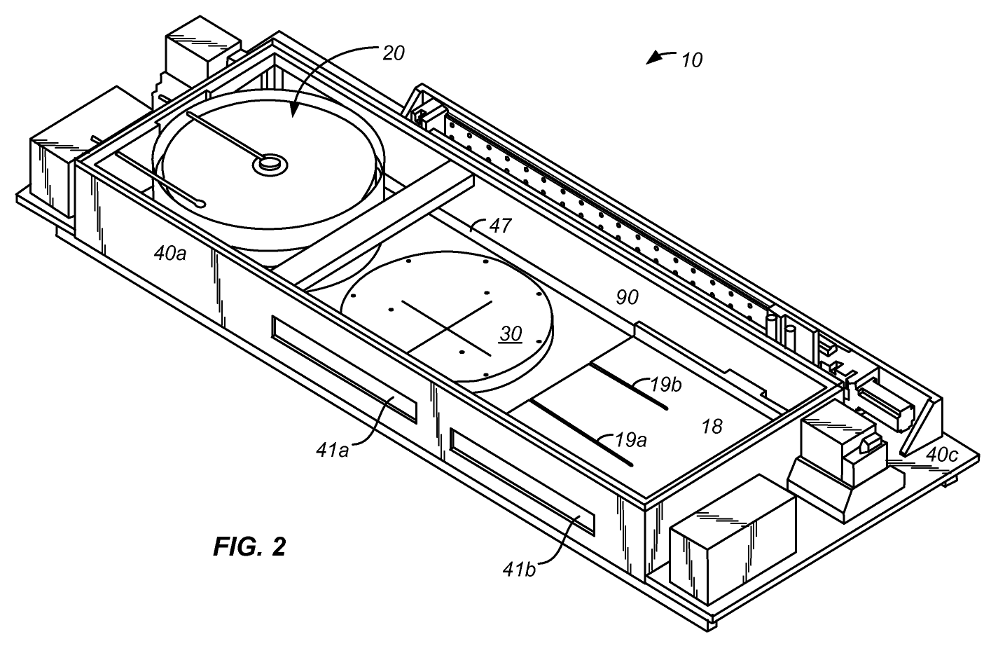

FIG. 2 is a simplified cut-away perspective view of a thermal unit according to an embodiment of the present invention. As illustrated in FIG. 2, the thermal unit 10 is shown in a cut-away view in which the top cover (not shown) is removed. The thermal unit 10 is serviced by a central robot through wafer transfer slots 41a and 41b in surface 40a. Generally, substrates enter the thermal unit through wafer transfer slot 41b and are placed on the shuttle 18, also referred to as a transfer shuttle. The shuttle delivers the substrate to the chill plate 30 and the clam shell enclosure 20 as appropriate to the particular thermal processes being performed on the substrate. The thermal unit 10 includes a shuttle 18, a chill plate 30, and clam shell enclosure 20 in which substrates are baked during portions of the lithography process. Lift pin slots 19a and 19b are provided in shuttle 18 to enable lift pins supporting the wafer to pass through the body of the shuttle. Also visible is a space 47 between rear support piece 90 of the housing and a bottom piece 40c. Space 47 extends along much of the length of thermal unit 10 to allow shuttle 18 to transfer wafers between bake and chill plates in the thermal unit.

Clam shell enclosure 20 contains a bake plate (not shown). In some embodiments, the bake plate is a multi-zone heater plate adapted to provide controlled heating to various portions of a substrate mounted on the bake plate. Additionally, some embodiments provide for a single-zone or multi-zone lid for the clam shell enclosure 20. Additional description of thermal units provided according to embodiments of the present invention is provided in co-pending and commonly assigned U.S. patent application Ser. No. 11/174,988, filed on Jul. 5, 2005 and hereby incorporated by reference in its entirety for all purposes.

Embodiments of the present invention are utilized in temperature controlled processes performed utilizing bake plates used for post-application-bake (PAB) and/or post-exposure-bake (PEB) processes. Uses are not limited to these processes as the cooling of temperature control structures are included within the scope of embodiments of the present invention. These other temperature control structures include chill plates, develop plates, and the like. One of ordinary skill in the art would recognize many variations, modifications, and alternatives.

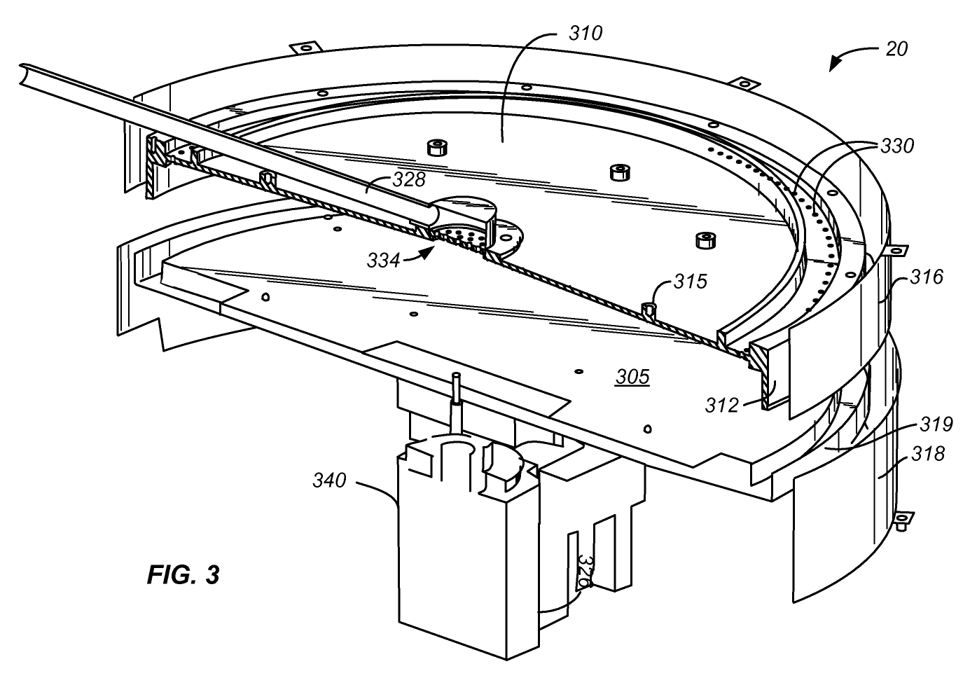

FIG. 3 is a perspective view of a cross-section of a bake station according to an embodiment of the present invention. As illustrated in FIG. 3, bake station 20 includes three separate isothermal heating elements: bake plate 305, top heat plate 310, and side heat plate 312, each of which is manufactured from a material exhibiting high heat conductivity, such as aluminum or other appropriate material. Each plate 305, 310, and 312 has a heating element, for example resistive heating elements, embedded within the plate. Bake plate 305 is generally fabricated from aluminum and the thickness of the bake plate is typically on the order of 10 mm. Bake station 20 also includes side, top and bottom heat shields 316 and 318, respectively, as well as a bottom cup 319 that surrounds bake plate 305. In an embodiment, each of heat shields 316, 318, and cup 319 are made from aluminum. A lid (not shown) is attached to top heat plate 310 by eight screws through threaded holes 315.

Bake plate 305 is operatively coupled to a motorized lift 340 so that the bake plate can be raised into the clam shell enclosure and lowered into a wafer receiving position. Typically, wafers are heated on bake plate 305 when it is raised to a baking position. When in the baking position, cup 319 encircles a bottom portion of side heat plate 312 forming a clam shell arrangement that helps confine heat generated by bake plate 305 within an inner cavity formed by the bake plate and the enclosure. In one embodiment, the upper surface of bake plate 305 includes 8 wafer pocket buttons and 17 proximity pins. Also, in one embodiment bake plate 305 includes a plurality of vacuum ports and can be operatively coupled to a vacuum chuck to secure a wafer to the bake plate during the baking process. In another embodiment, the bake plate includes an electrostatic chuck to secure the wafer to the bake plate during the baking process.

Gas is initially introduced into bake station 20 at an annular gas manifold 326 that encircles the outer portion of top heat plate 310. Gas manifold 326 includes numerous small gas inlets 330 (128 inlets in one embodiment) that allow gas to flow from manifold 326. After flowing through the station, gas exits bake station 20 through exhaust manifold 334 and gas outlet line 328.

Bake plate 305 heats a wafer according to a particular thermal recipe. One component of the thermal recipe is typically a set point temperature at which the bake plate is set to heat the wafer. During the baking process, the temperature of the wafer is routinely measured and one or more zones of the bake plate can be adjusted to ensure uniform heating of the substrate. Typically bake plate 305 is heated to the desired set point temperature while a large batch of wafers are processed according to the same thermal recipe. Thus, for example, if a particular thermal recipe calls for a set point temperature of 175° C. and that recipe is to be implemented on 100 consecutive wafers, bake plate 305 will be heated to 175° C. during the period of time it takes to process the 100 consecutive wafers. If, however, a subsequent batch of 200 wafers is to be processed according to a different thermal recipe, for example, that requires a set point temperature of 130° C., the set point temperature of bake plate 305 needs to be rapidly changed from 175° C. to 130° C. between processing wafer number 100 and wafer number 101. Embodiments of the present invention enable a rapid reduction in the set point temperature of bake plate 305, which helps minimize any delay associated with switching from one thermal recipe to another thermal recipe and thus helps ensure high wafer throughput through integrated thermal unit 10.

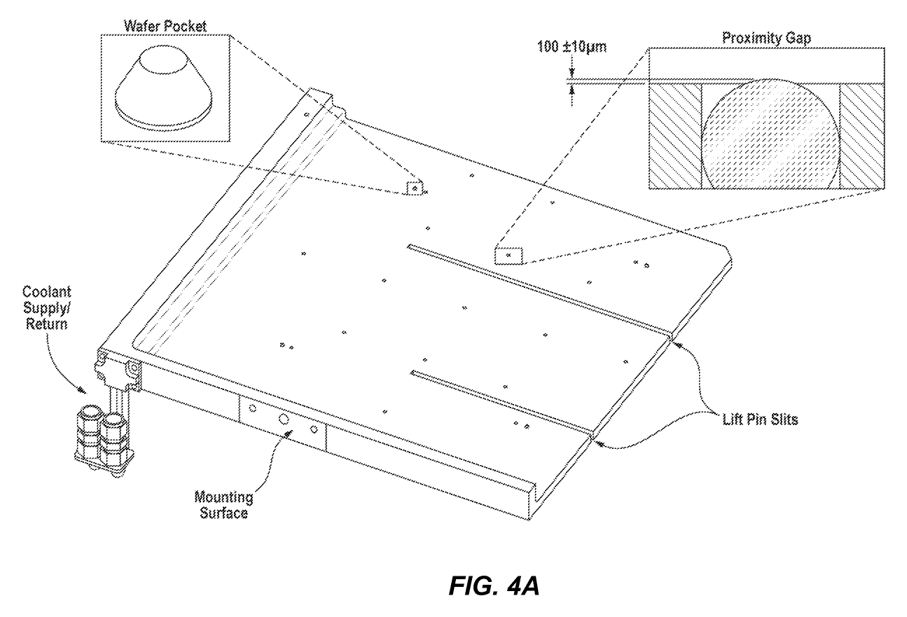

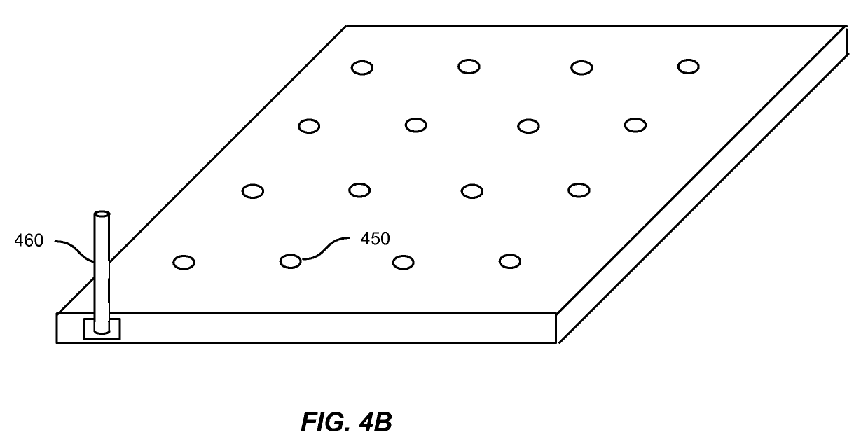

FIG. 4A is a first simplified perspective view of an actively chilled transfer shuttle according to an embodiment of the present invention. Heat transfer between the substrate and the actively chilled transport shuttle is provide through a number of proximity pins, which provide a proximity gap of 100±10 μm in the illustrated embodiment. A benefit provided by the proximity pins is a reduction in the formation of backside particles in contrast with the substrate contacting the transfer surface of the transport shuttle across the back surface of the substrate. As will be evident to one of skill in the art, the presence of particles has detrimental effects on other downstream processes. In an embodiment, the proximity gap is created by 17 2 mm diameter sapphire balls. The balls are crimped in place and height controlled by special CNC tooling. Additionally, a number, e.g., four, tapered buttons are used to center and hold the substrate. In alternative embodiments, other features are utilized to create the proximity gap while allowing for vacuum chucking. For example, both sapphire balls and centering features are replaced in one design with alumina cylinders. One of ordinary skill in the art would recognize many variations, modifications, and alternatives.

Two lift pin slits provide clearance for lift pins during the various pick and place moves. One or more cooling fluids are connected to the transfer shuttle. As described more fully throughout the present specification, one or more cooling fluids are provided to the actively chilled transfer shuttle to cool the shuttle and the bake plate. A first coolant (e.g., deionized water) circulating through internal channels in the shuttle provides for cooling of the shuttle. As illustrated in FIG. 4A, a return line is provide for circulation of this first coolant. A second coolant (e.g., helium gas) is expelled from ports on a lower surface of the transfer shuttle as illustrated in FIG. 4B and is used to cool the bake plate when the transfer shuttle is positioned above the bake plate. An additional supply line, as illustrated in FIG. 4B, is provided for this second coolant.

In an embodiment, the actively chilled transfer shuttle is fabricated of 6061-T6 aluminum with a TUFRAM™ coating. TUFRAM™ is a General Magnaplate proprietary coating. The coating is essentially an anodized coating impregnated with a “Teflon-like” material. A benefit provided by this coating is the ease of cleaning, which results from the reduced friction. Another benefit is the increased wear resistance as compared to a hard anodized coating. Generally, the transfer shuttle is fabricated from a thermally conductive material, for example, metal. In a particular embodiment, the transfer shuttle has a thickness of about 10 and is fabricated from aluminum, which has a high thermal capacity. In other embodiments, other suitable materials with appropriate thicknesses are utilized as will be evident to one of skill in the art.

FIG. 4B is a second simplified perspective view of an actively chilled transfer shuttle according to an embodiment of the present invention. As illustrated in FIG. 4B, the lower surface of the transfer shuttle, referred to as a cooling surface, includes a number of orifices 450 in fluid communication with a source of a cooling fluid. The cooling fluid is provided through supply line 460 and flows to the various orifices 450 through internal supply lines (not shown). In a specific embodiment, the cooling fluid is a cooling gas provided from an external source (not shown) and connected to the shuttle using the coolant supply line 460. Although a single supply line 460 is illustrated in FIG. 4B, additional supply lines are provided in alternative embodiments. One of ordinary skill in the art would recognize many variations, modifications, and alternatives.

Helium is utilized as the cooling gas in some implementations. Utilizing helium as the conductive cooling gas, embodiments of the present invention provide for low-cost cooling solutions. The inventors have calculated that the amount of helium utilized to accomplish a set point change for typical process conditions will be on the order of 25 cents. The increase in process chamber throughput provided herein more than offsets the cost of the process gas. Additionally, since helium is an inert gas, the flow of helium has no adverse effect on the process or in contamination of the chamber. Moreover, helium is readily available in wafer fabrication facilities.

Heat absorbed by the transport shuttle is removed by conduction to the cooling fluid flowing through the channels in the shuttle. As an example, the cooling fluid may be water (e.g., chilled water). The prompt transfer of the bake plate heat to the actively chilled transfer shuttle reduces the thermal impact of the heated bake plate on the bake plate environment. Since the specifications on the thermal uniformity of the bake plate are generally increasing as critical dimensions decrease, embodiments of the present invention provide the important benefit of reducing the variability of the thermal environment of the bake plate.

According to embodiments of the present invention, a method of rapidly cooling bake plates is provided in which no physical contact is made between the cooling element and the bake plate. As will be evident to one of skill in the art, particles may lead to the formation of defects during the semiconductor fabrication process. Thus, embodiments of the present invention may be used to cool the bake plate with minimal to no contamination of the bake plate surface.

The use of the existing transport shuttle as a heat sink for cooling the bake plate provides this non-contact functionality as described throughout the present specification. A benefit provided by embodiments of the present invention is that no additional hardware is utilized, reducing system complexity and increasing system reliability. In a particular embodiment, the transfer shuttle provided in existing chamber configurations, which is actively cooled or chilled, is used to start the process of removing heat from the bake plate. As an example, a set point change process can be implemented using the cooling ability provided by the actively chilled transport shuttle. Using only existing process chamber hardware, the bake chamber is able to modulate the temperature set point of the bake plate over a wide range of temperatures in a self-sufficient manner.

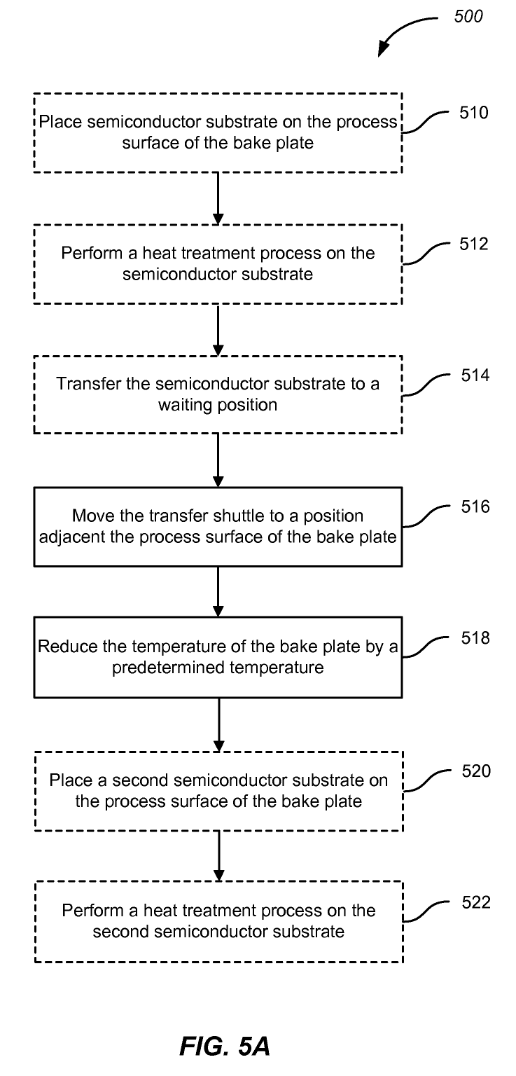

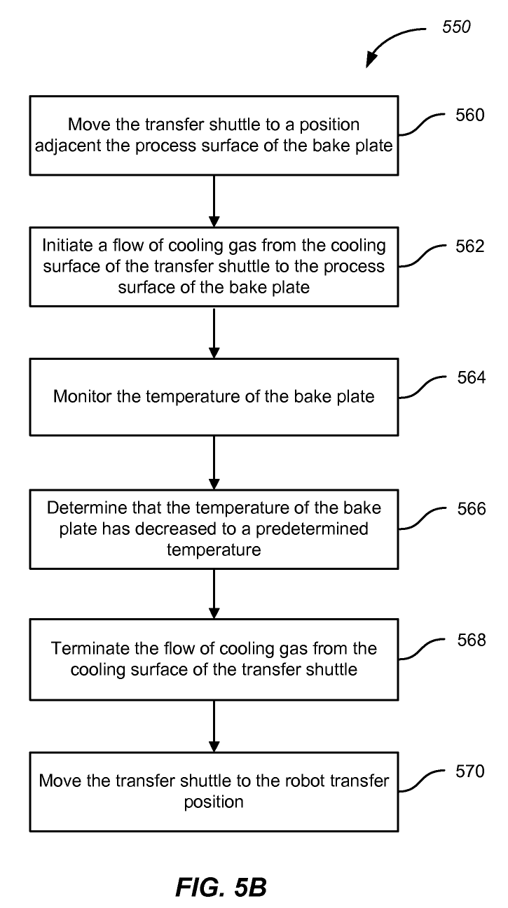

FIG. 5A is a simplified flowchart illustrating a method of performing a set point change for a semiconductor bake plate according to an embodiment of the present invention. Set point temperature change processes are provided herein. During semiconductor lithography operations, it is typical to process a first lot of substrates or wafers using a first process characterized by a first set of processing parameters. Preferably, each of the wafers in the lot experiences a consistent process history (i.e., wafer history). A second lot may then be processed with a second set of processing parameters. Between processing of the first lot and the second lot, it may be appropriate to modify set point temperatures of one or more bake plates provided in the track lithography tool. In order to improve system throughput and reduce delay between the processing of subsequent wafer lots, embodiments of the present invention decrease the time used to perform set point changes between wafer lots.

The set point change process 500 optionally includes placing a semiconductor substrate on a process surface of the bake plate (510) and performing a heat treatment process on the semiconductor substrate (512). A variety of heat treatment processes are included within the scope of the present invention, including PAB, PEB, and the like. In a particular embodiment, the semiconductor substrate processed in step 512 is the last substrate in a first lot of substrates. The substrate is then transferred to a waiting position (514) at the completion of the heat treatment process using the actively chilled transfer shuttle. For example, the substrate may be placed on a chill plate adapted to perform a cooling process on the substrate.

The actively chilled transfer shuttle is moved to a position adjacent the process surface of the bake plate (516). In an embodiment, the actively chilled transfer shuttle is positioned so that the cooling surface of the actively chilled transfer shuttle opposes the process surface of the bake plate. For example, the distance between the bottom of the transfer shuttle (cooling surface) and the top of the bake plate (process surface) is a predetermined distance. In an embodiment, the predetermined distance ranges from about 1 mm to about 5 mm. In a particular embodiment, the predetermined distance is about 2 mm.

After the transfer shuttle in a position above the bake plate, the distance between the transfer shuttle and the bake plate may be modified as appropriate to the particular cooling implementation. Thus, utilizing both lateral and vertical movement of the transfer shuttle (or the bake plate), the cooling surface of the transfer shuttle is placed opposite the process surface of the bake plate. The positions of the bake plate and the transfer shuttle, which are at different temperatures, will result in heat transfer occurring between the two structures via conduction across the gap between the structures. For a gap ranging from a fraction of a millimeter to several millimeters, conduction through the air between the cooling surface of the transfer shuttle and the process surface of the bake plate will result in cooling of the bake plate. As will be evident to one of skill in the art, the rate at which the bake plate temperature is reduced will be a function of the gap between the actively chilled transfer shuttle and the bake plate. The presence of the actively chilled shuttle adjacent the process surface of the bake plate will result in the temperature of the bake plate being reduced to a predetermined temperature (518). In some set point temperature change operations, the temperature of the bake plate is reduced by a temperature of 25° C. In other applications, the temperature is reduced by a temperature ranging from about 5° C. to about 50° C. The actual temperature change effected and the final bake plate temperature will depend on the particular application, for example, the process flows for the first wafer lot and the process flows for the second wafer lot.

A second semiconductor substrate is optionally placed on the process surface of the bake plate using the actively chilled transfer shuttle (520). Typically, step 520 will include multiple sub-steps such as picking up the wafer at a waiting position, translating the actively chilled transfer shuttle to a position adjacent the bake plate, supporting the wafer above the bake plate on lift pins, retracting the actively chilled transfer shuttle, retracting the lift pins, and the like. One of ordinary skill in the art would recognize many variations, modifications, and alternatives. An optional heat treatment process is then performed on the second substrate (522). In a particular embodiment, the second semiconductor substrate is a first substrate of a second wafer lot. After the set point change effected by steps 516 and 518, the temperature of the bake plate is prepared at the temperature appropriate to the processing of the second wafer lot as illustrated by step 522.

It should be appreciated that the specific steps illustrated in FIG. 5A provide a particular method of performing a set point change for a semiconductor bake plate according to an embodiment of the present invention. Other sequences of steps may also be performed according to alternative embodiments. For example, alternative embodiments of the present invention may perform the steps outlined above in a different order. Moreover, the individual steps illustrated in FIG. 5A may include multiple sub-steps that may be performed in various sequences as appropriate to the individual step. Furthermore, additional steps may be added or removed depending on the particular applications. One of ordinary skill in the art would recognize many variations, modifications, and alternatives.

In order to increase the heat transfer rate between the bake plate and the actively chilled transfer shuttle, some embodiments of the present invention flow a cooling gas through one or more orifices provided on the cooling surface of the actively chilled transfer shuttle. FIG. 5B is a simplified flowchart illustrating another method (550) of performing a set point change for a bake plate according to an alternative embodiment of the present invention. As shown in the method illustrated by FIG. 5B, the actively chilled transfer shuttle is moved to a position adjacent the process surface of the bake plate (560). Typically, the set point change process illustrated in FIG. 5B is performed after a first wafer lot is processed using the bake plate as discussed in relation to FIG. 5A. Thus, a series of heat treatment processes are performed on the wafers in the first lot and the set point change process is performed after the last wafer in the first wafer lot is removed from the bake plate and transferred to a waiting position such as a chill plate.

A flow of cooling gas is initiated so that a cooling gas flows from the cooling surface of the transfer shuttle to the process surface of the bake plate (562). The introduction of a cooling gas (e.g., air, nitrogen, helium, combinations thereof, and the like) into the gap between the bake plate and the actively chilled transfer shuttle decreases the cooling time for the bake plate. The use of a more conductive gas, for example, helium, will further decrease the cooling time for the bake plate. Additionally, the time to equilibrate the temperature across the bake plate is reduced, since the uniformity of heat removal by the shuttle is higher than for conventional heat removal mechanisms. In other embodiments, a cooling fluid such as liquid nitrogen or liquid helium is provided from the orifices on the cooling surface of the actively chilled transfer shuttle. Depending on the particular design, a combination of liquid and gas may be provided. One of ordinary skill in the art would recognize many variations, modifications, and alternatives.

The temperature of the bake plate is monitored (566) while the cooling gas impinges on the process surface of the bake plate. Thermocouples in thermal communication with the process surface or other portions of the bake plate are generally used to monitor the temperature of the bake plate. A determination is made that the temperature of the bake plate has decreased to a predetermined temperature (568). Merely by way of example, the predetermined temperature may be greater, equal to, or less than the desired temperature set point. In a first example, the temperature drop effected during process 550 places the bake plate at a temperature greater than the desired set point temperature although this is not required by the present invention. For such applications, an additional temperature drop occurs as the temperature settles to the desired set point temperature. In a second example, the predetermined temperature is less than the desired set point temperature and heating of the bake plate is used to adjust the temperature of the bake plate to the desired set point temperature.

The flow of cooling gas from the cooling surface of the actively chilled transfer shuttle is terminated (568) and the actively chilled transfer shuttle is moved to a robot transfer position (570). The timing of the termination of the cooling gas flow may be coordinated with the temperature monitoring process in step 564 in order to achieve a desired temperature set point. In some embodiments, the robot transfer position is adjacent a chill plate provided in the track lithography tool.

It should be appreciated that the specific steps illustrated in FIG. 5B provide a particular method of performing a set point change for a semiconductor bake plate according to a particular embodiment of the present invention. Other sequences of steps may also be performed according to other embodiments. For example, alternative embodiments of the present invention may perform the steps outlined above in a different order. Moreover, the individual steps illustrated in FIG. 5B may include multiple sub-steps that may be performed in various sequences as appropriate to the individual step. Furthermore, additional steps may be added or removed depending on the particular applications. One of ordinary skill in the art would recognize many variations, modifications, and alternatives.

As demonstrated by the computations described below, embodiments of the present invention provide for rapid decreases in bake plate temperature. For example, in some applications, a temperature reduction of 25° C. in a time period of 3 minutes is produced. Of course, in other applications, different temperature drops in different time periods are provided as appropriate to the particular application. One of ordinary skill in the art would recognize many variations, modifications, and alternatives.

Table 1 shows a calculation of the rate of cooling for a bake plate with a flow of 75% helium using a 2 mm gap between the process surface of the bake plate and the cooling surface of the transfer shuttle. These computations were performed using the relevant heat transfer equations. As illustrated in the last two lines of Table 1, the time taken for the bake plate to stabilize at the new set point temperature is 2.32 minutes using a 2 mm gap and 1.54 minutes using a 1 mm gap.

TABLE 1

| Variable | Value | Units |
|---|---|---|
| 75% He thermal conductivity | 0.113475 | W/m-K |
| Gap (bake plate to transfer shuttle) | 2 | mm |
| Temperature difference (bake plate to transfer | 130 | ° C. |
| shuttle) | | |
| Rate of heat loss/area | 7375.88 | W/m² |
| Bake plate cooling rate | 521.37 | W/s |
| ΔT bake plate | 25.00 | ° C. |
| Bake Plate Energy Transfer | 49197.34 | Joules |

| | | | |
|---|---|---|---|
| Bake plate cooled and stable at: | 2.32 | min | at 2 mm gap |
| Bake plate cooled and stable at: | 1.54 | min | at 1 mm gap |

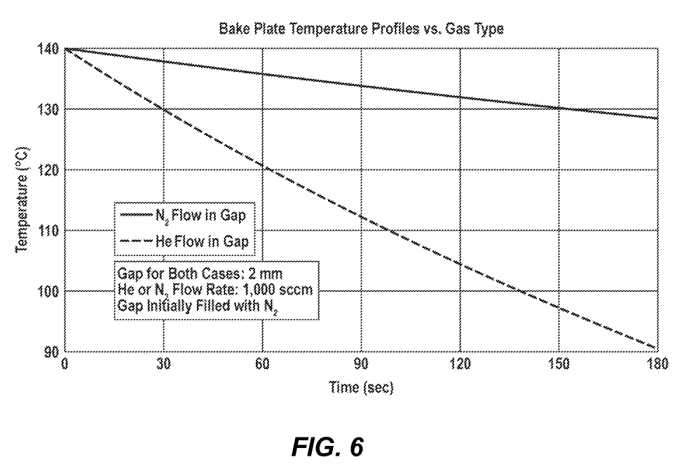

FIG. 6 is a simplified plot of the bake plate temperature profile as a function of time according to embodiments of the present invention. FIG. 6 illustrates the results of a detailed computer simulation result using computational fluid dynamics software and the actual geometry of the actively chilled transport shuttle. Referring to FIG. 6, using a helium flow in the gap, the temperature of the bake plate drops more than 25° C. in 90 seconds. Including an additional time of 45 seconds to account for the proportional integral derivative (PID) stabilization at the new temperature, these values are in accordance with the computations summarized in Table 1. Referring to FIG. 6, it will be noted that cooling of the bake plate using N₂ is slower than cooling using helium, on the order of 4° C./min. Thus, in some applications utilizing N₂ as the cooling gas expelled from orifices 450 on the cooling surface of the transfer shuttle, cooling of the bake plate will take more than 7 minutes to reach a set point achieved using helium flow in about 2 minutes. Modification of the gap between the actively chilled transport shuttle and the bake plate, the flow rate of the cooling fluid, and the like, will vary the rates at which temperature drops are observed. One of ordinary skill in the art would recognize many variations, modifications, and alternatives.

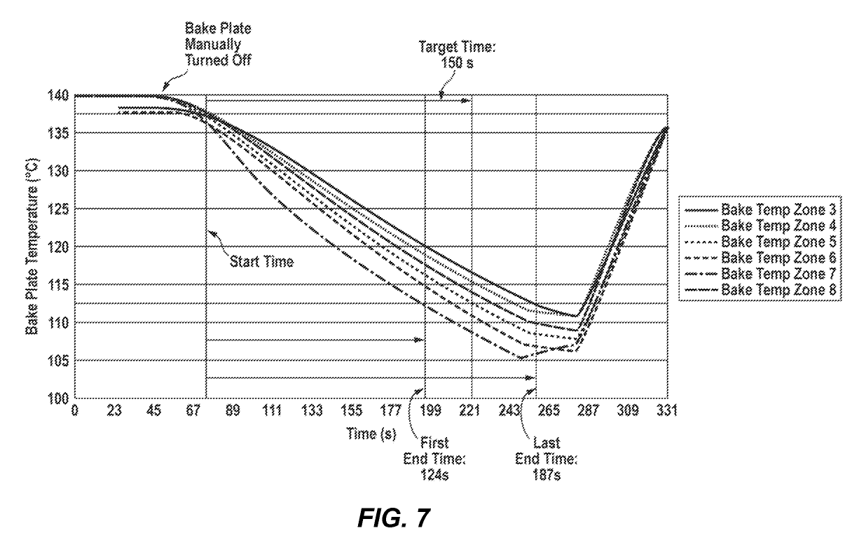

FIG. 7 is a simplified plot of bake plate zone temperatures as a function of time according to an embodiment of the present invention. The bake plate temperatures displayed in FIG. 7 were measured using a test bed developed by the present inventors. The bake plate utilizes six independently controlled temperature zones (Bake Temp Zone 3-Bake Temp Zone 8). Embodiments of the present invention are not limited to utilization in combination with a zone control bake plate, but may also be utilized in conjunction with single zone bake plates. The temperatures of thermal sensors in each of the zones are plotted in FIG. 7 as a function of time.

Referring to FIG. 7, the bake plate temperature was observed to decrease about 25° C. in about 140 seconds. Variations in temperature readings were observed between the various zones although the temperatures of all zones decreased during the cooling process. Without limiting embodiments of the present invention, the inventors believe that the variations in the measured data presented in FIG. 7 and the theoretical data presented in FIG. 6 resulted from variations in the gap between the actively chilled transport shuttle and the bake plate during measurement. It is further believed that reductions in gap variations will cause the experimental and theoretical results to align more closely.

In an alternative embodiment of the present invention, a method is provided in which the cooling surface of the actively chilled transfer shuttle is placed in contact with bake plate. In order to provide the desired temperature drop in the bake plate, the transfer shuttle may be left in contact with the bake plate for a predetermined time, or until a predetermined temperature drop has been achieved. Thus, the transfer shuttle may rest on the surface of the bake plate in some methods provided herein. In this alternative embodiment, a thermal interface material is attached to the cooling surface of the transfer shuttle to provide for appropriate heat transfer between the bake plate and the transfer shuttle

While the present invention has been described with respect to particular embodiments and specific examples thereof, it should be understood that other embodiments may fall within the spirit and scope of the invention. The scope of the invention should, therefore, be determined with reference to the appended claims along with their full scope of equivalents.

What is claimed is:

1. A method of performing a set point change process for a bake plate of a semiconductor process tool, the method comprising:
moving an actively chilled transfer shuttle to a position adjacent a process surface of the bake plate, wherein the actively chilled transfer shuttle comprises a transfer surface and a cooling surface opposing the transfer surface;
monitoring a temperature of the bake plate;
reducing the temperature of the bake plate to a predetermined temperature; and
moving the actively chilled transfer shuttle to a robot transfer position.

2. The method of claim 1 further comprising:
placing a semiconductor substrate associated with a first wafer lot on a process surface of the bake plate;
performing a first heat treatment process on the semiconductor substrate;
transferring the semiconductor substrate to a waiting position;
performing the set point change process recited in claim 1;
placing a second semiconductor substrate associated with a second wafer lot on the process surface of the bake plate;
performing a second heat treatment process on the second semiconductor substrate; and
transferring the second semiconductor substrate to the waiting position.

3. The method of claim 2 wherein the first heat treatment process and the second heat treatment process comprise at least one of a post-apply bake process or a post-exposure bake process.

4. The method of claim 1 further comprising flowing a cooling gas through one or more orifices provided on the cooling surface of the actively chilled transfer shuttle.

5. The method of claim 4 wherein the cooling gas comprises at least one of air, nitrogen, or helium.

6. The method of claim 4 wherein the cooling gas impinges on the process surface of the bake plate.

7. The method of claim 4 further comprising terminating a flow of the cooling gas prior to moving the actively chilled transfer shuttle to the robot transfer position.

8. The method of claim 1 wherein the predetermined temperature is greater than 10° C. less than an initial temperature of the bake plate.

9. The method of claim 1 wherein the semiconductor process tool comprises a track lithography tool.

10. The method of claim 1 wherein moving the actively chilled transfer shuttle to a position adjacent the process surface of the bake plate comprises positioning the cooling surface of the actively chilled transfer shuttle to oppose the process surface of the bake plate.

11. The method of claim 10 wherein the position adjacent the process surface of the bake plate comprises a position above the process surface of the bake plate.

12. The method of claim 10 further comprising modifying a distance between the cooling surface of the actively chilled transfer shuttle and the process surface of the bake plate.

13. The method of claim 10 wherein the cooling surface of the actively chilled transfer shuttle is free from physical contact with the process surface of the bake plate.

14. A method of performing a temperature set point change for a bake plate of a track lithography tool, the method comprising:
positioning a cooling surface of an actively chilled transfer shuttle adjacent a process surface of the bake plate, wherein the actively chilled transfer shuttle comprises the cooling surface and a transfer surface opposing the cooling surface;
monitoring a temperature of the bake plate;
initiating a flow of a cooling fluid through one or more orifices provided on the cooling surface of the actively chilled transfer shuttle;
determining that the temperature of the bake plate has decreased by a predetermined temperature;
terminating the flow of the cooling fluid; and
moving the actively chilled transfer shuttle to a robot transfer position.

15. The method of claim 14 wherein the cooling fluid impinges on the process surface of the bake plate.

16. The method of claim 14 wherein the predetermined temperature is at least 10° C. less than an initial temperature of the bake plate measured when positioning the cooling surface of the actively chilled transfer shuttle adjacent the process surface of the bake plate.

17. The method of claim 14 wherein the cooling fluid comprises a cooling gas.

18. The method of claim 17 wherein the cooling gas comprises at least one of air, nitrogen, or helium.

19. The method of claim 14 wherein positioning the cooling surface of the actively chilled transfer shuttle comprises positioning the cooling surface of the actively chilled transfer shuttle a predetermined distance from the process surface of the bake plate.

20. The method of claim 18 wherein the cooling surface of the actively chilled transfer shuttle is free from physical contact with the process surface of the bake plate.

21. The method of claim 19 further comprising modifying the predetermined distance between the cooling surface of the actively chilled transfer shuttle and the process surface of the bake plate.
